(19) United States
(12) Patent Application Publication
(10) Pub. No.: US 2024/0184939 A1
(43) Pub. Date: Jun. 6, 2024

(54) ORBITAL DESIGN SYSTEM FOR GLOBAL CARBON INVENTORY SATELLITE

(71) Applicants: INNOVATION ACADEMY FOR MICROSATELLITES OF CAS, Shanghai (CN); SHANGHAI ENGINEERING CENTER FOR MICROSATELLITES, Shanghai (CN)

(72) Inventors: Longfei TIAN, Shanghai (CN); Zengshan YIN, Shanghai (CN); Guohua LIU, Shanghai (CN); Denghui HU, Shanghai (CN); Zeying DONG, Shanghai (CN); Wenjuan GU, Shanghai (CN); Shuang GAO, Shanghai (CN); Zhiqiang WAN, Shanghai (CN); Yang LIU, Shanghai (CN)

(73) Assignees: INNOVATION ACADEMY FOR MICROSATELLITES OF CAS, Shanghai (CN); SHANGHAI ENGINEERING CENTER FOR MICROSATELLITES, Shanghai (CN)

(21) Appl. No.: 18/285,856

(22) PCT Filed: Jun. 30, 2021
(86) PCT No.: PCT/CN2021/103428

§ 371 Date: Oct. 5, 2023

(51) Int. Cl. G06F 30/15

(52) U.S. Cl. CPC G06F 30/15

(57) ABSTRACT

The present invention provides an orbit design system for a global carbon inventory satellite, comprising: a long residence unit in the northern hemisphere, configured to enable the global carbon inventory satellite operates in a mid-orbit elliptical orbit, and enable the global carbon inventory satellite to be located above the latitude of the human activity intensive region when it operates to its apogee.

### TECHNICAL FIELD

The present invention relates to the field of carbon emission technology, and in particular to an orbit design system for global carbon inventory satellite.

### BACKGROUND

Quantitative monitoring and assessment of carbon emissions is an important basis for realizing greenhouse gas emission reductions. Changes in atmospheric carbon dioxide concentration can reflect both anthropogenic carbon emissions and carbon absorption. Countries around the world are competing to develop space-based greenhouse gas monitoring systems to meet the major demand for global carbon inventory verification. Higher demands are now being placed on the monitoring of anthropogenic carbon emissions, and high-timeliness carbon monitoring needs to be carried out for the global human activity intensive regions.

At present carbon monitoring satellites mainly use low-orbit sun-synchronous orbits, although such satellites can achieve global coverage, they have lower orbital positions, restricted widths, long target revisit cycles and relatively uniform global coverage, and they are unable to make encrypted observations of key human activity intensive regions, and cannot achieve the high-precision and high-timeliness monitoring of human activity intensive regions that is required for global carbon inventory. In addition, high-orbit carbon monitoring satellites use geosynchronous orbit and are positioned over a certain region, but a single satellite cannot achieve global coverage, does not have global coverage capability and can only observe within a latitude and longitude span of ±50°, with the position of the fixed point as the center.

### SUMMARY

The object of the present invention is to provide an orbit design system for global carbon inventory satellite, so as to solve the problem that the orbit design of existing single carbon monitoring satellite is difficult to realize high-precision and high-timeliness monitoring of global carbon inventory.

To solve the above technical problems, the present invention provides an orbit design system for a global carbon inventory satellite, comprising:

A long residence unit in the northern hemisphere, configured to enable the global carbon inventory satellite to operate in a mid-orbit elliptical orbit, and enable the global carbon inventory satellite to be located above the latitude of the human activity intensive region when it operates to its apogee.

Optionally, in the orbit design system of the global carbon inventory satellite, further comprising:

A frozen orbit unit, configured to set a special orbital inclination so that the global carbon inventory satellite also operates in a frozen orbit, the apogee of the frozen orbit being frozen over the latitude of the human activity intensive region;

A sun-synchronous orbit unit, configured to set synchronization parameters so that the global carbon inventory satellite also operates in a sun-synchronous orbit, so that the global carbon inventory satellite is always in the light area when it operates to the apogee; and

A regression orbit unit, configured to enable the global carbon inventory satellite to also operate in a regression orbit, obtaining observation conditions consistent with the previous regression cycle.

Optionally, in the orbit design system of the global carbon inventory satellite, the latitude of the human activity intensive region is between 20°N and 45°N;

The synchronization parameters comprise orbital inclination, orbit half-length axis and orbit eccentricity;

The observation conditions comprise satellite elevation angle and solar altitude angle of the observation point; and

The orbital parameters of the global carbon inventory satellite comprise:

The range of perigee orbital altitude is 350 km-1000 km, the range of apogee orbital altitude is 6800 km-8300 km, the range of perigee argument is 215°-235°, and the orbital period is 3 h.

Optionally, in the orbit design system of the global carbon inventory satellite, the mid-orbit elliptical orbit is divided into a prograde elliptical frozen orbit and a retrograde elliptical frozen orbit according to the size of the critical inclination angle, the orbital inclination of the prograde elliptical frozen orbit is 63.4°, and the orbital inclination of the retrograde elliptical frozen orbit is 116.565°; and

According to the requirement that the ascending node of the sun-synchronous orbit moves eastward about 0.9856° every day, the orbital inclination of the global carbon inventory satellite is selected as 116.565°.

Optionally, in the orbit design system of the global carbon inventory satellite, the relationship between the perigee orbital altitude and the apogee orbital altitude is obtained according to the value of the ascending node of the sun-synchronous orbit, the value of the orbital inclination, the first function and the second function;

The first function represents the relationship between the semi-major axis of the orbit on one hand and the perigee orbital altitude and the apogee orbital altitude on the other hand; and

The second function represents the relationship between the orbital eccentricity on one hand and the perigee orbital altitude and the apogee orbital altitude on the other hand.

Optionally, in the orbit design system of the global carbon inventory satellite, the precession angular rate of the orbital plane is

$$\dot{Ω} = - 9.964 \times {( \frac{{R}_{e}}{a} )}^{3.5} \times {( 1 - {e}^{2} )}^{- 2} \times cos i ( ° / day )$$

Wherein, Rₑ is the radius of the Earth, a is the semi-major axis of the orbit, e is the orbital eccentricity, and i is the orbital inclination;

The value of the ascending node of the sun-synchronous orbit satisfies the following conditions:

$$\dot{Ω} = - 9.964 \times {( \frac{{R}_{e}}{a} )}^{3.5} \times {( 1 - {e}^{2} )}^{- 2} \times c o s i = 0.985612 \; 288 ( ° / day )$$

Wherein, the orbital inclination is 116.565°;

The first function is a=(hₚ+hₐ)/2+R_{E};

The second function is

$$e = 1 - \frac{{h}_{p} + {R}_{E}}{( {h}_{p} + {h}_{a} ) / 2 + {R}_{E}} ;$$

Wherein, hₚ is the perigee orbit altitude, hₐ is the apogee orbit altitude, and R_{E} is the radius of the Earth;

The orbital inclination, the first function and the second function are substituted to obtain the combination equations of the perigee orbital altitude hₚ and the apogee orbital altitude hₐ; and

The orbital altitude relationship curve is obtained according to the combination equations.

Optionally, in the orbit design system of the global carbon inventory satellite, after the regression orbit passing through a regression cycle, the sub-satellite point trajectory overlaps with the sub-satellite point trajectory of the previous regression cycle:

D*×2π=N×Δλ

Wherein, N is the number of orbits of the satellite orbiting the Earth in a regression period. D* is the number of ascending days in the regression period, and Δλ is the traverse angle;

The perigee orbit altitude and the apogee orbit altitude are synchronously adjusted, while ensuring the constraint of the sun-synchronous orbit, and design of the orbit period. orbit precession, and the Earth's rotation speed is matched to obtain the regression orbit; and

The points on the orbital altitude relationship curve are selected based on the Q value, and the parameters of the regression orbit are calculated iteratively in the range of the mid-orbit elliptical orbit with the perigee orbit altitude of 350 km-1000 km, the apogee orbit altitude of 6800 km-8300 km, and orbital inclination of 116.565°.

Optionally, in the orbit design system of the global carbon inventory satellite, the apogee of the global carbon inventory satellite is set over a specific latitude in the northern hemisphere by adjusting the argument of the perigee, so that the transit time of the global carbon inventory satellite in the northern hemisphere in the region of more intensive human activities is longer, in order to observe the northern hemisphere for a longer period of time; and

According to the proportional relationship between the argument of perigee and the latitude of apogee, the argument of perigee is determined, 35 degrees of north latitude is selected as the position of apogee, and 220 degrees is selected as the perigee argument of the global carbon inventory satellite.

Optionally, in the orbit design system of the global carbon inventory satellite, the working arc segment of the global carbon inventory satellite load is at the apogee of the northern hemisphere according to the working characteristics of the global carbon inventory satellite, so that the satellite flight direction in the light area is an ascending orbit, so as to realize:

The satellite has no sunlight in the shadow area of the Earth and consumes battery power. After entering the light area, the satellite is located in the southern hemisphere, carrying out observation missions while the solar panels are recharged in preparation for long-duration observations in the northern hemisphere; and

After the satellite enters the light area, the external heat flow reaches temperature equilibrium, and the satellite reaches a stable thermal equilibrium state prior to centralized observation in the northern hemisphere in order to enhance the data quality of the infrared channel.

Optionally, in the orbit design system of the global carbon inventory satellite:

When the satellite is at different latitudes, the local time of the sub-satellite point changes, and the corresponding solar elevation changes accordingly;

When the local time of the descending node is 0 o'clock, the local time curves of the sub-satellite point of different latitudes are drawn, wherein the horizontal axis is latitude, the southern latitude is negative, the northern latitude is positive, from left to right is an orbit-raising process, and the vertical axis is the local time of the sub-satellite point;

When the satellite is at southern latitude, the local time is afternoon; when the satellite crosses the equator, the local time is 12 noon; when observing in the northern hemisphere. the local time is morning, wherein a typical orbit near the apogee of 35°N. latitude has a local time of about 10:45 am; and

According to the actual need to translate the right ascension of the ascending node, the local time will be shifted accordingly, and the adjustment method is as follows: for every 15° increase in the right ascension of the ascending node, the local time of the corresponding sub-satellite point will be increased by one hour.

In the orbit design system of the global carbon inventory satellite provided by the present invention, the global carbon inventory satellite operates in a mid-orbit elliptical orbit, and when the global carbon inventory satellite operates to its apogee, it is located above the latitude of the human activity intensive region. Due to the altitude of apogee is higher and the flight speed in the vicinity of the apogee is slower, global carbon inventory satellite can achieve long-term resident observation of the region of intensive human activities in the northern latitude (including Asia, North America, and Europe).

The apogee of the global carbon inventory satellite in the present invention is frozen over the latitude of the region of intensive human activities, which can ensure the maximization of the observation time for the northern hemisphere; it is always in the light area at the apogee, thus ensuring the relatively consistent light conditions for the observation, which is conducive to the realization of high-precision inversion of the carbon dioxide column concentration.

The present invention synchronously adjusts the altitude of the perigee and apogee of the orbit through coupling design, while ensuring the sun-synchronous characteristics of the orbit, matching design of the orbit period, orbit precession, and the rotation speed of the Earth, etc., to find the regression orbit. The regression characteristics of the orbit can ensure the periodic repeatability of the ground trajectory, thus obtaining consistent observation conditions, such as the satellite elevation angle and solar altitude angle of the observation point, which is conducive to the simplification of the design of the satellite working mode.

The global carbon inventory satellite in the present invention operates in a mid-orbit elliptical frozen sun-synchronous regression orbit, which can achieve global coverage, a higher orbital position, a larger width, and a short target revisit cycle; and it is capable of realizing high-time-frequency scanning encrypted observation for key human activity intensive regions during transit.

### BRIEF DESCRIPTION OF THE DRAWINGS

FIG. 1 is a schematic diagram of the operational orbit of a global carbon inventory satellite according to an embodiment of the present invention;

FIG. 2 is a schematic diagram illustrating the corresponding relationship between the perigee and apogee of the elliptical frozen sun-synchronous orbit of the global carbon inventory satellite according to an embodiment of the present invention;

FIG. 3 is a schematic diagram of the sub-satellite point trajectory of the elliptical frozen sun-synchronous regression orbit of the global carbon inventory satellite according to an embodiment of the present invention;

FIG. 4 is a schematic diagram illustrating the corresponding relationship between the argument of perigee and the latitude of apogee of the global carbon inventory satellite according to an embodiment of the present invention; and

FIG. 5 is a schematic diagram of the local time difference of the sub-satellite points at different latitudes of the global carbon inventory satellite according to an embodiment of the present invention.

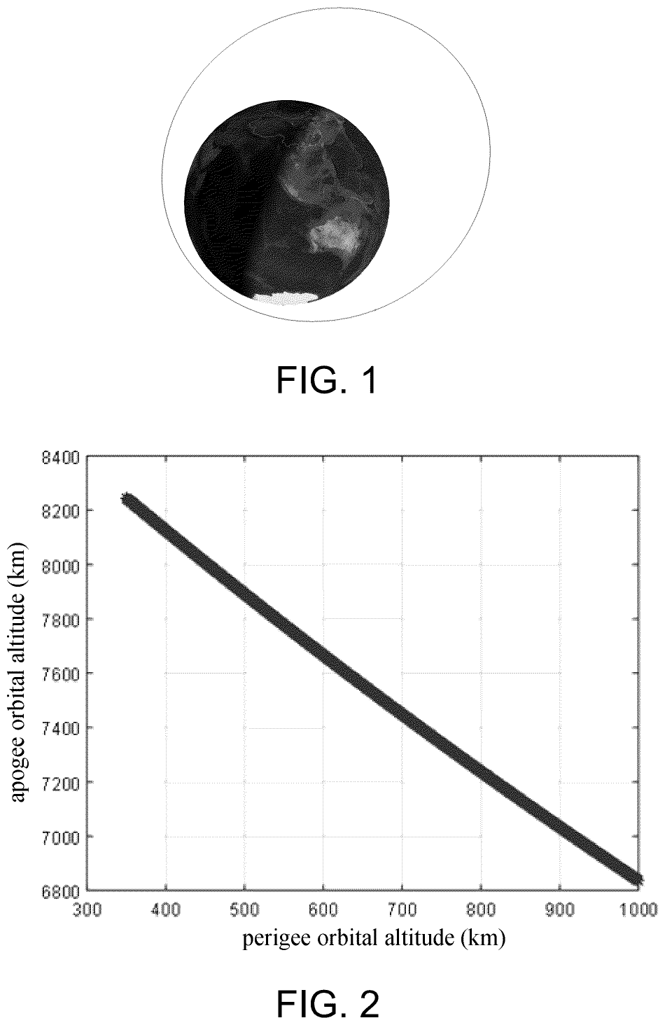

### DETAILED DESCRIPTION OF EMBODIMENTS

In the present invention, the embodiments are merely intended to illustrate the scheme of the present invention and should not be construed as limiting.

It should also be noted that, within the scope of the present invention, the terms “the same”, “equal”, “equal to”, etc. do not mean that the two numerical values are absolutely equal, but rather allow for a certain reasonable error, that is to say, the terms also cover “substantially the same”, “substantially equal” and “substantially equal to”.

In addition, the numbering of the steps of various methods of the present invention does not limit the order in which the steps of the method are performed. Unless otherwise indicated, the steps of various methods may be performed in a different order.

The orbital design system for the global carbon inventory satellite proposed in the present invention is described in further detail below in conjunction with the accompanying drawings and specific embodiments. The advantages and features of the present invention will become clearer according to the following description and claims. It should be noted that the accompanying drawings are in a very simplified form and use non-precise proportions, used only for convenience and clarity assisting in the illustration of the purpose of embodiments of the present invention.

The object of the present invention is to provide an orbit design system for a global carbon inventory satellite, so as to solve the problem that the orbit design of existing single carbon monitoring satellite is unable to realize high-precision and high-timeliness monitoring of global carbon inventory.

In order to achieve the above objects, the present invention provides an orbit design system for a global carbon inventory satellite, comprising: a long residence unit in the northern hemisphere, configured to enable the global carbon inventory satellite operates in a mid-orbit elliptical orbit, and enable the global carbon inventory satellite to be located above the latitude of the human activity intensive region when it operates to its apogee; a frozen orbit unit, configured to set a special orbital inclination so that the global carbon inventory satellite also operates in a frozen orbit, the apogee of the frozen orbit being frozen over the latitude of the human activity intensive region; a sun-synchronous orbit unit, configured to set synchronization parameters so that the global carbon inventory satellite also operates in a sun-synchronous orbit, so that the global carbon inventory satellite is always in the light area when it operates to the apogee.

Embodiments of the present invention provide an orbit design system for a global carbon inventory satellite, comprising: a long residence unit in the northern hemisphere, configured to enable the global carbon inventory satellite to operate in a mid-orbit elliptical orbit, and when the global carbon inventory satellite operates to its apogee, it is located above the latitude of the human activity intensive region. Ordinary low-orbit sun-synchronous orbits generally adopt circular orbits with an orbital altitude of 500 km to 1,000 km, and their flight speeds are 7.3 km/s to 7.6 km/s, corresponding to ground speeds at the sub-satellite point are 6.4 km/s to 7.1 km/s. Due to the low flight altitude and high speed, the transit times to specific regions on the ground are shorter, and it is impossible to carry out large-scope scanning and monitoring. However, the global carbon inventory satellite in this embodiment operates in a mid-orbit elliptical orbit, its apogee altitude is higher and speed flight in the vicinity of the apogee is slower. By setting the apogee over a specific latitude (e.g., 30°N latitude), it is able to achieve long-term resident observation of the region of intensive human activities in the northern latitude (including Asia, North America, and Europe).

In one embodiment of the present invention, in the orbit design system of the global carbon inventory satellite, further comprising: a frozen orbit unit, configured to set a special orbital inclination so that the global carbon inventory satellite also operates in a frozen orbit, the apogee of the frozen orbit being frozen over the latitude of the human activity intensive region; the argument of the perigee of a general elliptical orbit changes over time, i.e., precession occurs, leading to the latitudes of the perigee and the apogee are constantly changed, which cannot ensure long-term resident observation of the northern hemisphere region where the land and the population are more concentrated. The carbon inventory orbit proposed in the present invention adopts a special inclination angle design, which freezes the apogee over the northern hemisphere and ensures the maximization of the observation time in the northern hemisphere.

In one embodiment of the present invention, in the orbit design system of the global carbon inventory satellite, further comprising: a sun-synchronous orbit unit, configured to set synchronization parameters so that the global carbon inventory satellite also operates in a sun-synchronous orbit, so that the global carbon inventory satellite is always in the light area when it operates to the apogee; through the joint design of orbital inclination, orbital semi-major axis and eccentricity, the precession rate of the right ascension of the ascending node (RAAN) of the orbital plane is about 0.98 ° eastward per day, so as to realize the synchronous “tracking” of the sun. The orbit can ensure that the apogee is always in the light area, and the local time of the transit area in different orbits remains consistent (It is noted that there will be small changes in the local time of the sub-satellite point in one orbit), thus ensuring that the light conditions for observation are relatively consistent, which is conducive to the realization of high-precision carbon dioxide column concentration inversion.

In one embodiment of the present invention, in the orbit design system of the global carbon inventory satellite, further comprising: a regression orbit unit, configured to enable the global carbon inventory satellite to also operate in a regression orbit, obtaining observation conditions consistent with the previous regression cycle. Through the coupling design, the altitude of the perigee and apogee of the orbit are adjusted synchronously, while ensuring the sun-synchronous characteristics of the orbit, matching design of the orbit period, orbit precession, and the rotation speed of the Earth, etc., to find the regression orbit. The regression characteristics of the orbit can ensure the periodic repeatability of the ground trajectory, thus obtaining consistent observation conditions, such as the satellite elevation angle and solar altitude angle of the observation point, which is conducive to the simplification of the design of the satellite working mode.

In one embodiment of the present invention, in the orbit design system of the global carbon inventory satellite, the latitude of the human activity intensive region is between 20°N and 45°N; the synchronization parameters comprise orbital inclination, orbit half-length axis and orbit eccentricity; the observation conditions comprise satellite elevation angle and solar altitude angle of the observation point; the orbital parameters of the global carbon inventory satellite comprise: the range of perigee orbital altitude is 350 km-1000 km, the range of apogee orbital altitude is 6800 km-8300km, the range of perigee argument is 215°-235°, and the orbital period is 3 h.

In one embodiment of the present invention, in the orbit design system of the global carbon inventory satellite, the inclination angle of the elliptical frozen orbit is selected as follows: affected by the flatness of the Earth, the arch point of the elliptical orbit will precess over time, and when the known orbit inclination meets specific conditions, the precession rate of the arch point can be made to be 0, that is, the orbit arch point is realized to be “frozen”, such an orbit is called a frozen orbit, and the corresponding inclination angle is the critical inclination angle. The mid-orbit elliptical orbit is divided into a prograde elliptical frozen orbit and a retrograde elliptical frozen orbit according to the size of the critical inclination angle, the orbital inclination of the prograde elliptical frozen orbit is 63.4°, and the orbital inclination of the retrograde elliptical frozen orbit is 116.565°; considering the precession of the ascending node, the ascending node of the prograde orbit precesses westward by a certain angle every day, and the ascending node of the retrograde orbit precesses eastward by a certain angle every day, while the sun synchronization requires that the ascending node moves eastward by about 0.9856° per day, therefore, according to the requirements of the ascending node of the sun synchronous orbit, the orbital inclination of the global carbon inventory satellite is determined to be 116.565°.

In one embodiment of the present invention, in the orbit design system of the global carbon inventory satellite, the relationship between the perigee orbital altitude and the apogee orbital altitude is obtained according to the value of the ascending node of the sun-synchronous orbit, the value of the orbital inclination, the first function and the second function; the first function represents the relationship between the semi-major axis of the orbit on one hand and the perigee orbital altitude and the apogee orbital altitude on the other hand; the second function represents the relationship between the orbital eccentricity on one hand and the perigee orbital altitude and the apogee orbital altitude on the other hand.

In one embodiment of the present invention, in the orbit design system of the global carbon inventory satellite, the frozen characteristics of the elliptical orbit constrain the orbital inclination, and a joint design of the orbital semi-major axis and the orbital eccentricity is required under a specific orbital inclination condition. Due to the influence of the Earth's non-spherical gravitational perturbation, the orbital plane of the satellite continuously precesses in the inertial space. Only considering the long-term perturbation with harmonic term J₂, the precession angular rate of the orbital plane is

$$\dot{Ω} = - 9.964 \times {( \frac{{R}_{e}}{a} )}^{3.5} \times {( 1 - {e}^{2} )}^{- 2} \times cos i ( ° / day )$$

Wherein, Rₑ is the radius of the Earth, a is the semi-major axis of the orbit, e is the orbital eccentricity, and i is the orbital inclination;

The value of the ascending node of the sun-synchronous orbit satisfies the following conditions:

$$\dot{Ω} = - 9.964 \times {( \frac{{R}_{e}}{a} )}^{3.5} \times {( 1 - {e}^{2} )}^{- 2} \times cos i = 0.985612 \; 288 ( ° / day )$$

Wherein, the orbital inclination is 116.565°;

The first function is a=(hₚ+hₐ)/2+R_{E};

The second function is

$$e = 1 - \frac{{h}_{p} + {R}_{E}}{( {h}_{p} + {h}_{a} ) / 2 + {R}_{E}} ;$$

Wherein, hₚ is the perigee orbit altitude, hₐ is the apogee orbit altitude, and R_{E} is the radius of the Earth;

The orbital inclination, the first function and the second function are substituted to obtain the combination equations of the perigee orbital altitude hₚ and the apogee orbital altitude hₐ; the orbital altitude relationship curve is obtained according to the combination equations, as shown in FIG. 2. By traversing the altitude range of perigee hₚ from 350 km to 1000 km, the corresponding apogee orbital altitude can be obtained respectively, and the relationship between them is shown in FIG. 2. This is the design basis of the elliptical frozen sun-synchronous orbit, which shows that the higher the perigee altitude is, the lower the apogee altitude is.

The regression orbit design is more common in earth remote sensing satellites. The sub-satellite point trajectory of this orbit periodically overlaps, which can ensure the consistent elevation angle of the satellite during the transit period, and with the sun-synchronous characteristics of the orbit, it can achieve a more consistent observation light angle, which can simplify the design of the satellite operating mode. In one embodiment of the present invention, in the orbit design system of the global carbon inventory satellite, the sub-satellite point trajectory is a synthesis of the three motions of satellite flight, orbital plane precession and the Earth's rotation, and for the regression orbit, the regression orbit after passing through a regression cycle, the sub-satellite point trajectory overlaps with the sub-satellite point trajectory of the previous regression cycle:

D*×2π=N×Δλ

Wherein, N is the number of orbits of the satellite orbiting the Earth in a regression period, D* is the number of ascending days in the regression period, and Δλ is the longitude interval of successive adjacent trajectories on the equator, i.e. the traverse angle; The perigee orbit altitude and the apogee orbit altitude are synchronously adjusted, while ensuring the constraint of the sun-synchronous orbit, matching design of the orbit period, orbit precession, and the Earth's rotation speed to obtain the regression orbit;

The points on the orbital altitude relationship curve are selected based on the Q value, and the parameters of the regression orbit are calculated iteratively in the range of the mid-orbit elliptical orbit with the perigee orbit altitude of 350 km-1000 km, the apogee orbit altitude of 6800 km-8300 km, and orbital inclination of 116.565°. After analysis, there are a total of 14 groups of orbits satisfying the characteristics of elliptical+frozen+sun−synchronous+regression in this range, as shown in Table 1.

TABLE 1
Design of Elliptical Frozen Sun-synchronous Regression Orbit

| Serial | Perigee altitude | Apogee altitude | Regression |
|---|---|---|---|
| number | (km) | (km) | period (days) |
| 1. | 356.1 | 8228.99 | 8 |
| 2. | 373.9 | 8186.22 | 9 |
| 3. | 388.35 | 8151.7 | 10 |
| 4. | 522.2 | 7840.02 | 1 |
| 5. | 681.4 | 7487.47 | 9 |
| 6. | 664.9 | 7523.14 | 10 |
| 7. | 899.5 | 7033.96 | 4 |
| 8. | 818.15 | 7199.32 | 5 |
| 9. | 765.74 | 7308.22 | 6 |
| 10. | 729.11 | 7386.45 | 7 |
| 11. | 959.8 | 6914.17 | 7 |
| 12. | 702.1 | 7443.01 | 8 |
| 13. | 853.91 | 7126.09 | 9 |
| 14. | 984.51 | 6865.76 | 10 |

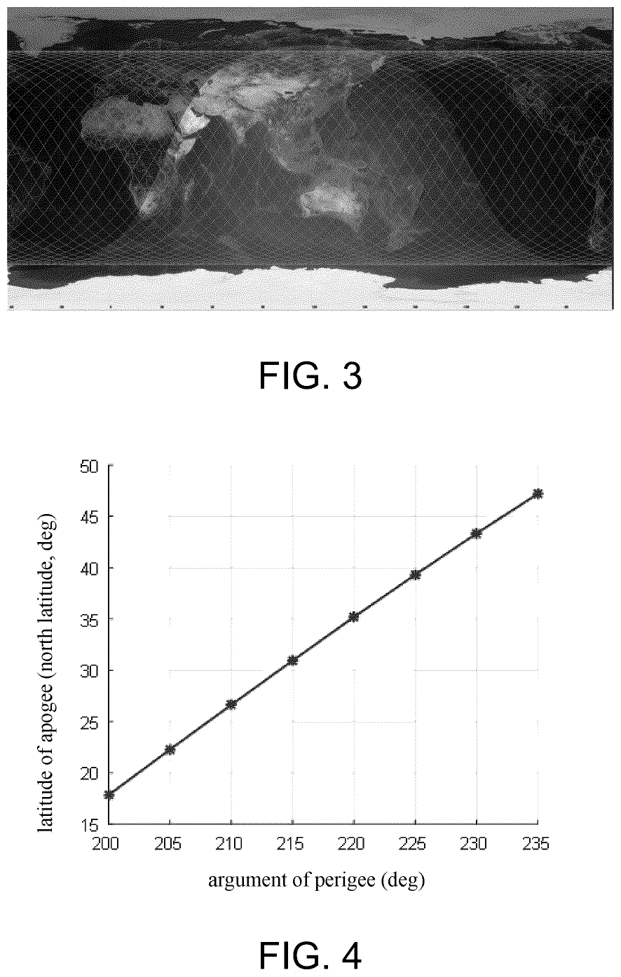

The 8th group of orbits in the table are selected as a typical carbon inventory orbit, with a regression period of 5 days, and the trajectory of the sub-satellite point over 5 days is shown in FIG. 3.

In one embodiment of the present invention, in the orbit design system of the global carbon inventory satellite, the adjustment of the argument of perigee does not affect the orbital period and the orbital plane precession rate, and thus does not affect the sun-synchronization characteristics and regression characteristics of the orbit. The apogee of the global carbon inventory satellite is set over a specific latitude in the northern hemisphere by adjusting the argument of the perigee, so that the transit time of the global carbon inventory satellite in the northern hemisphere in the region of more intensive human activities is longer, in order to observe the northern hemisphere for a longer period of time; taking the 5-day regression elliptical frozen sun-synchronous orbit with a perigee altitude of 818.15 km and an apogee altitude of 7.199.32 km as an example, the apogee latitudes corresponding to different perigee arguments are shown in FIG. 4. It can be seen from FIG. 4 that the larger the argument of perigee is, the higher the corresponding apogee latitude is. Comprehensively considering the latitudinal distribution of key countries such as China, the United States. Europe, Japan and India. selecting 35°N as the apogee position can achieve long-term resident observation of these key countries. Therefore, the perigee argument of the global carbon inventory satellite is selected to be 220°.

In one embodiment of the present invention, in the orbit design system of the global carbon inventory satellite, the working arc segment of the global carbon inventory satellite load is at the apogee of the northern hemisphere according to the working characteristics of the global carbon inventory satellite, so that the satellite flight direction in the light area is an ascending orbit (flying from south to north), so as to realize:

The satellite has no sunlight in the shadow area of the earth and consumes battery power. After entering the light area, the satellite is located in the southern hemisphere, with fewer observation missions, carrying out observation missions while the solar panels are recharged in preparation for long-duration observations in the northern hemisphere;

After the satellite enters the light area, the external heat flow changes, and it takes a period of time to reach temperature equilibrium. The ascending orbit in the light area can ensure that the satellite reaches a stable thermal equilibrium state prior to centralized observation in the northern hemisphere in order to enhance the data quality of the infrared channel.

Optionally, in the orbit design system of the global carbon inventory satellite:

When the satellite is at different latitudes, the local time of the sub-satellite point changes, and the corresponding solar elevation changes accordingly;

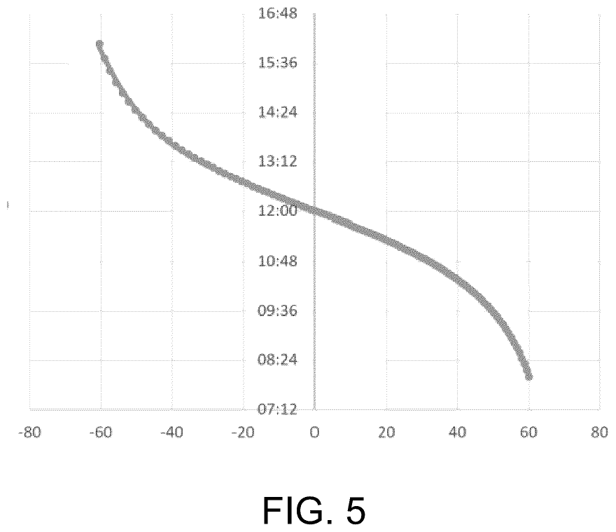

When the local time of the descending node is 0 o'clock, the local time curves of the sub-satellite point of different latitudes are drawn, as shown in FIG. 5, wherein the horizontal axis is latitude, the southern latitude is negative, the northern latitude is positive, from left to right is an orbit-raising process, and the vertical axis is the local time (24 h system) of the sub-satellite point;

When the satellite is at southern latitude, the local time is afternoon; when the satellite crosses the equator, the local time is 12 noon; when observing in the northern hemisphere. the local time is morning, wherein a typical orbit near the apogee of 35°N. latitude having a local time of about 10:45 am;

According to the actual need to translate the right ascension of the ascending node, the local time will be shifted accordingly, and the adjustment method is as follows: for every 15° increase in the right ascension of the ascending node, the local time of the corresponding sub-satellite point will be increased by one hour.

After the above design steps, a set of satellite orbit design results suitable for global carbon inventory are obtained, and the orbit parameters and orbit characteristics are shown in Table 2.

TABLE 2
Satellite Orbit Design suitable for Carbon Inventory

| Serial | Track Parameters & | |
|---|---|---|
| number | Characteristics | Value |
| 1. | Perigee altitude (km) | 818.15 |
| 2. | Apogee altitude (km) | 7199.32 |
| 3. | Eccentricity | 0.307175 |
| 4. | Orbital inclination (°) | 116.565 |
| 5. | Argument of perigee (°) | 220 |
| 6. | Local time at the descending | 00:00 am |
| | node | |
| 7. | Latitude of apogee | 35° N |
| 8. | Apogee sub-satellite point local | 10:45 am |
| | time | |
| 9. | Orbital period (H) | 2.92641 |
| 10. | Regression period (days) | 5 |

The revisit and coverage capability of the orbit are analyzed and compared it with low-orbit sun-synchronous orbit satellites and geosynchronous orbit satellites, the present invention provides an orbital design system for the global carbon inventory satellite, in which the global carbon inventory satellite operates in a mid-orbit elliptical orbit, and when the global carbon inventory satellite operates to its apogee, it is located above the latitude of the human activity intensive region. Due to the altitude of apogee is higher and the flight speed in the vicinity of the apogee is slower, global carbon inventory satellite can achieve long-term resident observation of the region of intensive human activities in the northern latitude (including Asia, North America, and Europe).

The apogee of the global carbon inventory satellite in the present invention is frozen over the latitude of the region of intensive human activities, which can ensure the maximization of the observation time for the northern hemisphere; it is always in the light area at the apogee, thus ensuring the relatively consistent light conditions for the observation, which is conducive to the realization of high-precision inversion of the carbon dioxide column concentration.

The present invention synchronously adjusts the altitude of the perigee and apogee of the orbit through coupling design, while ensuring the sun-synchronous characteristics of the orbit, matching design of the orbit period, orbit precession, and the rotation speed of the Earth, etc., to find the regression orbit. The regression characteristics of the orbit can ensure the periodic repeatability of the ground trajectory, thus obtaining consistent observation conditions, such as the satellite elevation angle and solar altitude angle of the observation point, which is conducive to the simplification of the design of the satellite working mode.

The global carbon inventory satellite in the present invention operates in a mid-orbit elliptical frozen sun-synchronous regression orbit, which can achieve global coverage, a higher orbital position, a larger width, and a short target revisit cycle; and it is capable of realizing high-time-frequency scanning encrypted observation for key human activity intensive regions during transit.

Although some embodiments of the present invention have been described in this application document, those skilled in the art can understand that these embodiments are only shown as examples. Numerous variation schemes, alternative schemes, and improvement schemes can be contemplated by those skilled in the art under the teachings of the present invention without exceeding the scope of the present invention. The appended claims are intended to limit the scope of the present invention and thereby cover methods and structures within the scope of the claims themselves and their equivalent electrical energy transformations.

1. An orbit design system for a global carbon inventory satellite, comprising:
a long residence unit in the northern hemisphere, configured to enable the global carbon inventory satellite to operate in a mid-orbit elliptical orbit, and enable the global carbon inventory satellite to be located above a latitude of a human activity intensive region when the global carbon inventory satellite operates to an apogee of the mid-orbit elliptical orbit.

2. The orbit design system for the global carbon inventory satellite according to claim 1, further comprising:
a frozen orbit unit, configured to set a special orbital inclination so that the global carbon inventory satellite also operates in a frozen orbit, an apogee of the frozen orbit being frozen over the latitude of the human activity intensive region;
a sun-synchronous orbit unit, configured to set synchronization parameters so that the global carbon inventory satellite also operates in a sun-synchronous orbit, so that the global carbon inventory satellite is always in the light area when the global carbon inventory satellite operates to an apogee of the sun-synchronous orbit; and
a regression orbit unit, configured to enable the global carbon inventory satellite to also operate in a regression orbit, obtaining observation conditions consistent with the previous regression cycle.

3. The orbit design system for the global carbon inventory satellite according to claim 2, wherein the latitude of the human activity intensive region is between 20°N and 45°N;
the synchronization parameters comprise orbital inclination, orbit half-length axis and orbit eccentricity;
the observation conditions comprise satellite elevation angle and solar altitude angle of the observation point; and
the orbital parameters of the global carbon inventory satellite comprise a range of a perigee orbital altitude, a range of an apogee orbital altitude and a range of a perigee argument, wherein the range of perigee orbital altitude is 350 km-1000 km, the range of apogee orbital altitude is 6800 km-8300 km, and the range of perigee argument is 215°-235°.

4. The orbit design system for the global carbon inventory satellite according to claim 3, wherein the mid-orbit elliptical orbit is divided into a prograde elliptical frozen orbit and a retrograde elliptical frozen orbit according to the size of the critical inclination, wherein the orbital inclination of the prograde elliptical frozen orbit is 63.4°, and the orbital inclination of the retrograde elliptical frozen orbit is 116.565°; and
the orbital inclination of the global carbon inventory satellite is selected as 116.565° according to a requirement regarding an ascending node of the sun-synchronous orbit moves eastward about 0.9856° every day.

5. The orbit design system for the global carbon inventory satellite according to claim 4, wherein a relationship between the perigee orbital altitude and the apogee orbital altitude is obtained according to a value of the ascending node of the sun-synchronous orbit, a value of the orbital inclination, a first function and a second function;
the first function represents the relationship between the semi-major axis of the orbit on one hand and the perigee orbital altitude and the apogee orbital altitude on the other hand; and
the second function represents the relationship between the orbital eccentricity on one hand and the perigee orbital altitude and the apogee orbital altitude on the other hand.

6. The orbit design system for the global carbon inventory satellite according to claim 5, wherein the precession angular rate of the orbital plane is
$$\dot{Ω} = - 9.964 \times {( \frac{{R}_{e}}{a} )}^{35} \times {( 1 - {e}^{2} )}^{- 2} \times cos i ( ° / day )$$
wherein, Rₑ is a radius of the Earth, a is a semi-major axis of the orbit, e is an orbital eccentricity, and i is an orbital inclination;
the value of the ascending node of the sun-synchronous orbit satisfies the following conditions:
$$\dot{Ω} = - 9.964 \times {( \frac{{R}_{e}}{a} )}^{35} \times {( 1 - {e}^{2} )}^{- 2} \times cos i = 0.985612288 ( ° / day )$$
wherein, the orbital inclination is 116.565°;
the first function is a=(hₚ+hₐ)/2+R_{E};
the second function is
$$e = 1 - \frac{{h}_{p} + {R}_{E}}{( {h}_{p} + {h}_{a} ) / 2 + {R}_{E}} ;$$
wherein, hₚ is a perigee orbit altitude, hₐ is an apogee orbit altitude, and R_{E} is the radius of the Earth;
the orbital inclination, the first function and the second function are substituted to obtain combination equations of the perigee orbital altitude hₚ and the apogee orbital altitude hₐ; and
an orbital altitude relationship curve is obtained according to the combination equations.

7. The orbit design system for the global carbon inventory satellite according to claim 6, wherein the regression orbit after passing through a regression period, a sub-satellite point trajectory of the current regression period overlaps with a sub-satellite point trajectory of the previous regression cycle:
D*×2π=N×Δλ
wherein, N is a number of orbits of the satellite orbiting the Earth in the regression period, D* is a number of ascending days in the regression period, and Δλ is a traverse angle;
the perigee orbit altitude and the apogee orbit altitude are synchronously adjusted, while ensuring the constraint of the sun-synchronous orbit, design of the orbit period, orbit precession, and the Earth's rotation speed is matched to obtain the regression orbit; and
the points on the orbital altitude relationship curve are selected based on the Q value, and the parameters of the regression orbit are calculated iteratively in the range of the mid-orbit elliptical orbit with the perigee orbit altitude of 350 km-1000 km, the apogee orbit altitude of 6800 km-8300 km, and orbit inclination of 116.565°.

8. The orbit design system for the global carbon inventory satellite according to claim 7, characterized in that, wherein
the apogee of the global carbon inventory satellite is set over a specific latitude in the northern hemisphere by adjusting the argument of the perigee, so that the transit time of the global carbon inventory satellite in the northern hemisphere in the region of more intensive human activities is longer, in order to observe the northern hemisphere for a longer period of time; and
according to the proportional relationship between the argument of perigee and the latitude of apogee, the argument of perigee is determined, 35 degrees of north latitude is selected as the position of apogee, and 220 degrees is selected as the perigee argument of the global carbon inventory satellite.

9. The orbit design system for the global carbon inventory satellite according to claim 8, wherein
the working arc segment of the global carbon inventory satellite load is at the apogee of the northern hemisphere, and the satellite flight direction in the light area is an ascending orbit;
the satellite has no sunlight in the shadow area of the Earth and consumes battery power, after entering the light area, the satellite is located in the southern hemisphere, carrying out observation missions while the solar panels are recharged in preparation for long-duration observations in the northern hemisphere; and
after the satellite enters the light area, the external heat flow reaches temperature equilibrium, and the satellite reaches a stable thermal equilibrium state prior to centralized observation in the northern hemisphere in order to enhance the data quality of the infrared channel.

10. The orbit design system for the global carbon inventory satellite according to claim 5, wherein
when the satellite is at different latitudes, a local time of the sub-satellite point changes, and the corresponding solar elevation changes accordingly;
when the local time of the descending node is 0 o′clock, local time curves of the sub-satellite point of different latitudes are drawn, wherein the horizontal axis is latitude, the southern latitude is negative, the northern latitude is positive, from left to right is an orbit-raising process, and the vertical axis is the local time of the sub-satellite point;
when the satellite is at southern latitude, the local time is afternoon; when the satellite crosses the equator, the local time is 12 noon; when observing in the northern hemisphere, the local time is morning, wherein a typical orbit near the apogee of 35°N. latitude having the local time of about 10:45 am; and
according to the actual need to translate the right ascension of the ascending node, the local time is shifted accordingly, and the adjustment method is as follows: for every 15° increase in the right ascension of the ascending node, the local time of the corresponding sub-satellite point is increased by one hour.
